(19) United States
(12) Patent Application Publication
(10) Pub. No.: US 2004/0178498 A1
(43) Pub. Date: Sep. 16, 2004

(54) Wire bonding to full array bonding pads on active circuitry

(76) Inventors: Qwai H. Low, Cupertino, CA (US); Ramaswamy Ranganathan, Saratoga, CA (US); Maniam Alagaratnam, Cupertino, CA (US); Chok J. Chia, Cupertino, CA (US)

Correspondence Address: LSI LOGIC CORPORATION, 1621 BARBER LANE, MS: D-106 LEGAL, MILPITAS, CA, 95035, US

(21) Appl. No.: 10/384,892

(22) Filed: Mar. 10, 2003

(51) Int. Cl. H01L 23/48

(52) U.S. Cl. 257/734

(57) ABSTRACT

A wire bond assembly includes a multitude of bond pads arranged in an array on the surface of a die among the active circuitry and wires for electrically connecting the bond pads on the die to the substrate. As the bond pads on the die are not limited to the perimeter of the die a greater density of bond pads can be achieved and therefore the overall dimensions of the die can be reduced.

### FIELD OF THE INVENTION

The present invention relates generally to wire bonding of pads on a die to leads on a package. More specifically the invention relates to providing a full array of bonding pads which can be wire bonded to the leads on a package.

### BACKGROUND OF THE INVENTION

Wire bonding is one technique which is used to make electrical connections between the bonding pads on a die and the leads on a package. In order to avoid contact between the wires used for bonding, the wire bond pads are typically located around the perimeter of the die. By placing the wires around the perimeter of the die, the possibility of the wires touching each other is decreased and therefore the likelihood of short out is decreased. However, restricting the boding pads to the die perimeter limits the number of bond pads that can be put on a die of a particular size. Thus, the die area of many devices is large because the size of the die is dictated by the number of pads or inputs/outputs are needed on the perimeter of the die. In these pad limited designs, the minimum size possible for the die is defined by the number of pads on the perimeter of the die, not the circuitry.

Increasing the size of the die needed to perform a particular function increases the cost of the device as fewer dies can be formed from each wafer. In addition, increasing the size of the die is particularly a problem in new sub-micron device technology.

One method currently used to minimize the size of the die is to increase the density of bonding pads by reducing the size of the bonding pads. Finer pitch bond pads, however, result in yield losses from wires shorting. This technique also requires finer bonding wires which results in an increased cost.

Another method currently used is to create two or three rows of bonding pads around the perimeter of the die. One problem with double or triple rows of bonding pads or other high density bonding pad methods is that there are many bonding wires in close proximity to each other. This close proximity can lead to wires coming into contact with each other during the wiring phase or in the molding process. If the wire comes into contact with another wire, then the device will not function properly.

The flip chip technique is another method used to provide connections between the pads and the leads without increasing the die area. However, not all devices or customers can use the flip chip techniques. In addition, flip chip is a more expensive packaging technology compared to wire bonding.

### OBJECTS AND SUMMARY

It is an object of an embodiment of the present invention to reduce the area of the die required to provide a certain number of die pads or inputs/outputs.

Another object of an embodiment of the present invention is to provide a greater density of pads on the die.

Still another object of an embodiment of the present invention is to reduce the possibility of the bonding wires from contacting each other and shorting out.

A further object of an embodiment of the present invention is to reduce the cost of forming the die.

Briefly, and in accordance with at least one of the foregoing objects, an embodiment of the present invention provides a wire bonded assembly. The wire bonded assembly includes a die with an array of bonding pads on its surface. The bonding pads are not only positioned around the perimeter of the die, but are also positioned on the center portion of the die, among active circuitry, preferably creating a dense arrangement of bond pads. Preferably, the bonding pads are wire bonded to the leads of the package substrate using insulated wires. Because the wires are insulated, contact between the wires is not a concern.

### BRIEF DESCRIPTION OF THE DRAWINGS

The present invention and the advantages thereof will become more apparent upon consideration of the following detailed description when taken in conjunction with the accompanying drawings, wherein like reference numeral represent like elements and wherein:

FIG. 1 illustrates approximately one quarter of a wire bond assembly of the present invention;

FIG. 2 represents an electrical connection between a bond pad and a lead in accordance with the teachings of the present invention; and

FIGS. 3-5 represent different methods of forming a wire bond assembly of the present invention.

### DESCRIPTION

While the invention may be susceptible to embodiment in different forms, there are shown in the drawings, and herein will be described in detail, specific embodiments with the understanding that the present disclosure is to be considered an exemplification of the principles of the invention, and is not intended to limit the invention to that as illustrated and described herein.

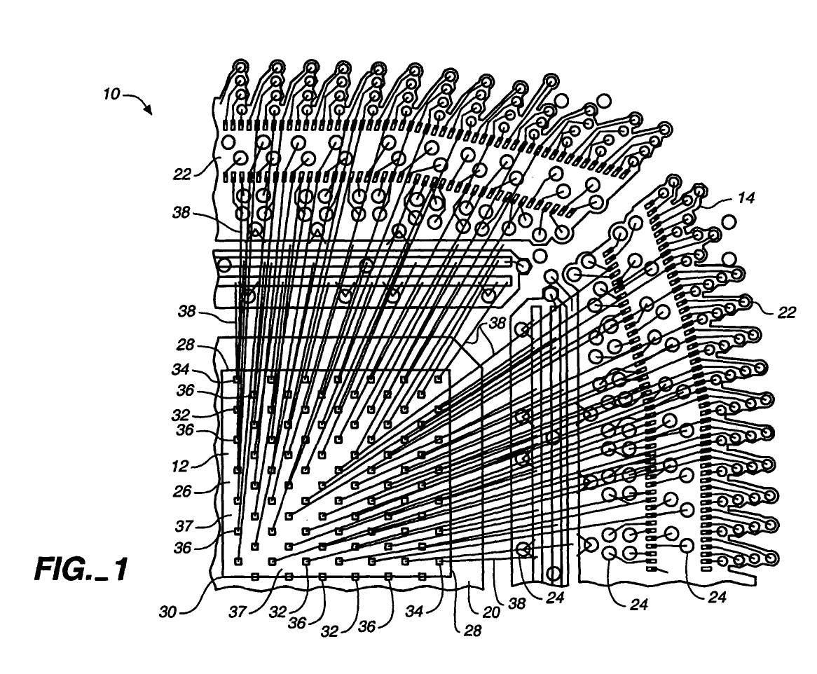

The wire bonded assembly 10 of the present invention, one quarter of which is shown, is illustrated in FIG. 1. The assembly 10 generally includes a die 12 (one quarter of which is shown) and a package substrate 14 (one quarter of which is shown). The remaining second, third and fourth quarters of the die 12 are mirror images of the quarter shown in FIG. 1. Likewise, the remaining second, third and fourth quarter of the package substrate 14 are mirror images of the quarter shown in FIG. 1.

The substrate package 14 includes a surface 16. The surface 16 of the substrate package 14 includes a perimeter (not shown) and a mounting area 20 and a lead area 22. The surface 16 of the substrate is generally formed of an insulative material. The mounting area 20 is generally located in the center of the surface 16. The lead area 22 generally extends from the perimeter of the substrate package 14 to the mounting area 20.

A plurality of leads 24 are dispersed within the lead area 22. The leads 24 are formed from a conductive material and as shown in FIG. 1 are in the form of plated through holes.

The die 12 is positioned within the mounting area 20. The surface 26 of the die 12 includes a perimeter 28 and a center point 30. Bond pads 32 are dispersed on the surface 26 of the die 12. The bond pads 32 are formed from a conductive material. A perimeter row 34 of bond pads 32 is positioned on a portion of said die proximate the perimeter 28 of the die 12. Inner rows 36 of bond pads 32 are positioned between the perimeter row 34 and the center point 30 on an inner portion of the die 12. As shown in FIG. 1, the perimeter row 34 and the inner rows 36 of bond pads 32 form an array which covers the entire surface of the die 12 and is not limited to the perimeter of the die 12. Preferably, the bond pads 32 are dispersed among active circuitry 37 (i.e., among the cells, transistors and circuitry of the device, as opposed to being provided merely along the peripheral edge such as among metallization or bare silicon areas which do not have any transistors or metal circuitry).

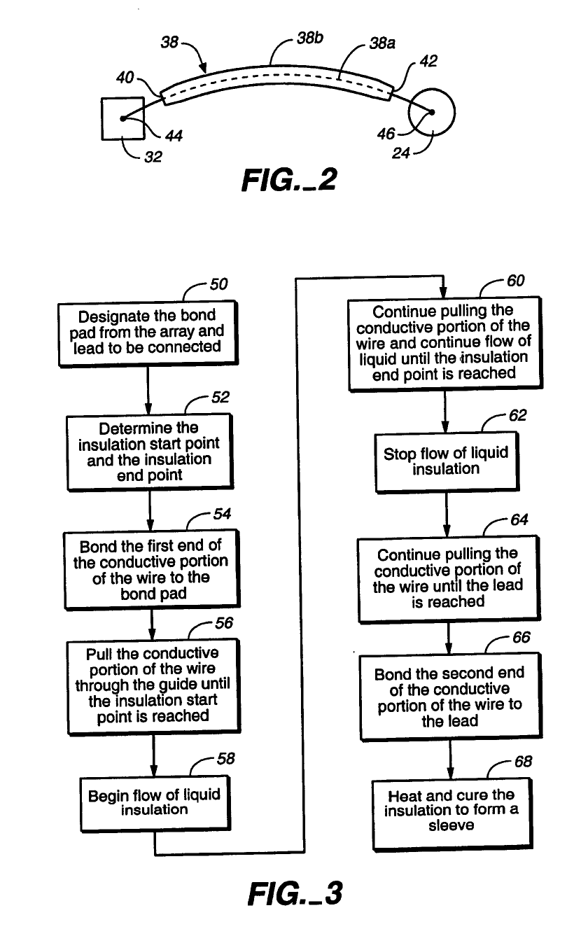

A plurality of wires 38 extend between the bond pads 32 and the leads 24. As best shown in FIG. 2, each wire 38 preferably includes a conductive portion 38a and an insulative sleeve 38b. The conductive portions 38a of the wires 38 provide electrical connections between the bond pads 32 and the leads 24 allowing, for example, electrical signals to be transmitted between the bond pads 32 and the leads 24. The sleeve 38b electrically insulates each conductive portion 38a of the wires 38 from the conductive portions 38a of the remaining wires 38. Many of the wires 38 may contact other wires 38, however, the sleeves 38b prevent shorting out between the wires 38. The sleeves 38b allow the bond pads 32 and the wires 38 to be densely arranged as there is no concern as to whether the wires 38 contact one another.

While it is preferred that the wires 38 be insulated, it does not matter which method is used to insulate the wires 38. In fact, many different methods of insulating the conductive portions 38a of the wires 38 can be used. One method of insulating the conductive portions 38a, for example, includes use of a insulating liquid to form the sleeves 38b and is illustrated in FIG. 3. In this method, the conductive portions 38a of the wires 38 are insulated as they are connected between the bond pads 32 and the leads 24, as shown in FIG. 2.

To begin, a bond pad 32 from the array of bond pads on the surface of the die is designated to be connected to a designated lead 24, step 50, FIG. 3. Next, an insulation start point 40 and an insulation end point 42 are determined, step 52, FIG. 3. The insulation start point 40 is a predetermined distance from the designated bond pad 32 and the insulation end point 42 is a predetermined distance from the designated lead 24. A first end 44 of the conductive portion 38a of the wire 38 is then bonded to the designated bond pad 32, step 54, FIG. 3. The conductive portion 38a of the wire 38 is then pulled through a guide which is moved in a direction toward the designated lead 24, step 56, FIG. 3. As the conductive portion 38a of the wire 38 is pulled through the guide and when the insulation start point 40 is reached, a liquid is flowed on the wire 38, step 58, FIG. 3. The conductive portion 38a of the wire 38 continues to be pulled through the guide and the insulation continues to flow on the conductive portion 38a of the wire 38 until the insulation end point 42 is reached, step 60, FIG. 3. When the insulation end point 42 is reached, the flow of the liquid insulation is stopped, step 62, FIG. 3. The conductive portion 38a continues to be pulled through the guide until the conductive portion 38a reaches the lead 24, step 64, FIG. 3. The second end 42 of the conductive portion 38a is then bonded to the lead 24, step 66, FIG. 3. The liquid is then heated to cure the insulator, forming a fine thin sleeve 38b around the conductive portion 38a of the wire 38, step 68, FIG. 3.

As shown in FIG. 2, the sleeve 38b extends from the insulation start point 40 to the insulation end point 42 and therefore does not interfere with bonding of the conductive portion 38a to the designated bond pad 32 and the designated lead 24. The bond pads 32 and the leads 24 are spaced apart a predetermined distance and therefore, contact between the wires near the bond pads 32 and the leads 24 is not a concern. The sleeve 38b fully coats the conductive portion 38a of the wire 38 between the insulation start point 40 and the insulation end point 42, therefore, there is no concern regarding the conductive portion 38a of the wire 38 contacting the conductive portion 38a of another wire 38.

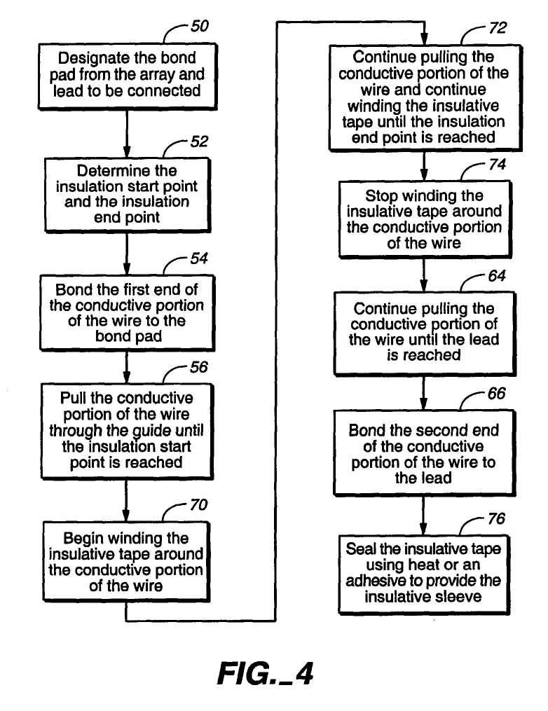

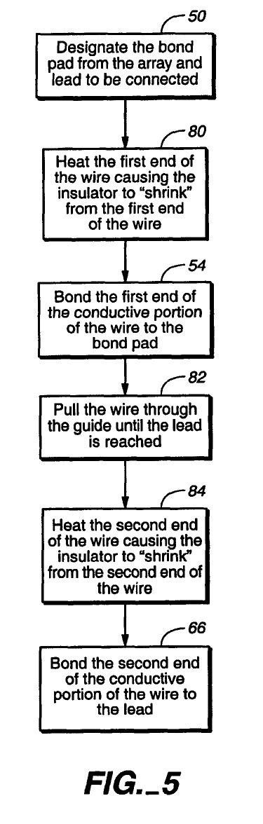

Another method which can be used to insulate the conductive portion 38a of the wire 38 is shown in FIG. 4 and includes use of a flat insulative tape. In this method, as the conductive portion 38a of the wire 38 is pulled from the bond pad 32 to the lead 24, a tape is wrapped around the conductive portion 38a as it is pulled from the guide. The steps of this method are identical to the steps described above and represented in FIG. 3 with the following exceptions. Step 58 which provides that the flow of liquid insulation begins, in this method is replaced with the step of “begin winding the insulative tape around the conductive portion of the wire”, step 70, FIG. 4. Step 60 which provides that pulling of the wire is to continue while the flow of liquid continues, in this method is replaced with “Continue pulling the conductive portion of the wire and the continue winding the insulative tape until the insulation end point is reached, step 72, FIG. 4. Likewise, step 62 which provides that the flow of liquid insulation stops, in this method is replaced with “stop winding the insulative tape around the conductive portion of the wire”, step 74, FIG. 4. Finally, step 68, which provides for heating and curing the insulation, is replaced with “seal the insulative tape using heat or an adhesive to provide an insulative sleeve”, step 76, FIG. 4. As with the previously described method of insulating the wire, an insulation start point, spaced from the bond pad 32, and an insulation end point, spaced from the lead 24, are defined. The insulative sleeve 38b extends from the insulation start point 40 to the insulation end point 42 and, therefore, does not interfere with the process of bonding the conductive portion 38a to the bond pad 32 and the lead 24. Another method of insulating the conductive portions 38a of the wires 38 is shown in FIG. 5 and involves use of wire which includes a conductive portion 38a covered with a “heat shrink” material along its entire length. As with the previous methods, this method begins by designating a contact pad 32 from the array of contact pads and the lead 24 to be electrically connected. To bond the first end 44 of the conductive portion 38a, the first end 44 of the wire 38 is first heated causing the insulator to “shrink” from the first end 44 and expose the conductive portion 38a of the wire 38, step 80, FIG. 5. The first end 44 of the conductive portion 38a is then bonded to the bond pad 32. The wire is then pulled through the guide until the lead is reached, step 82, FIG. 5. Next, the second end 46 of the wire 38 is heated causing the insulator to “shrink” from the second end 46 and expose the conductive portion 38a of the wire 38, step 84, FIG. 5. The second end 46 of the conductive portion 38a is then bonded to the lead 24. As a result, an insulative sleeve 38b extends from the insulation start point 40 to the insulation end point 42 of the wire 38.

Still another method of insulating the wires involves insulating the wires after they have been wire bonded. For example, a coating can be applied after wire bonding to keep the wires separated and insulated for molding. It should be pointed out again that the present invention does not necessarily require that the wires be insulated, and that if the wires are insulated any method of insulating the wire can be used.

The wire bond assembly 10 allows for a high density of the bonding pads 32 without the increased cost due to using a finer bonding wire. The assembly 10 provides for a die area which relates to the active circuitry i.e. with the wire bond assembly 10, it is not necessary to provide additional die area to allow for additional inputs/outputs around the perimeter of the die. By using this approach to bonding the die pads to the package, short circuits due to wires 38 contacting each other is eliminated.

As each of the wires 38 includes an insulative sleeve 38b, the density of the wires 38 can be increased and even smaller die size and packages can be achieved. For example, in traditional wire bonding techniques a certain spacing between the bond pads is required to avoid short outs during the wiring and molding processes. As each of the wires 38 includes a sleeve 38b, these short outs are not an issue. Therefore, the spacing requirements can be reduced. Also, additional height is not required to provide spacing between the wires 38, therefore, the package height can be made smaller than the height necessary for conventional wire bonding techniques.

While embodiments of the present invention are shown and described, it is envisioned that those skilled in the art may devise various modifications of the present invention without departing from the spirit and scope of the appended claims.

What is claimed is:

1. A wire bond assembly comprising:
a die, wherein a surface of said die includes a perimeter portion and an inner portion having active circuitry thereon;
a plurality of bond pads on a surface of said die, wherein said bond pads are located in said perimeter of said die and said inner portion of said die among said active circuitry;
a package substrate;
a plurality of leads on said package substrate; and
a plurality of wires connecting certain of said bond pads to certain of said leads.

2. A wire bond assembly as defined in claim 1, further including insulation covering each of said wires.

3. A wire bond assembly as defined in claim 1, wherein said insulation covers a portion of each of said wires.

4. A wire bond assembly as defined in claim 1, wherein said bonds pads are arranged in an array including a plurality of columns and a plurality of rows.

5. A wire bond assembly as defined in claim 1, wherein said bond pads are arranged on the entire surface of the die and the entire surface of the die is related to the active area of the die.

6. A wire bond assembly as defined in claim 1 wherein said plurality of wires is insulated with a cured liquid.

7. A wire bond assembly as defined in claim 1, wherein said plurality of wires is insulated with a flat tape.

8. A wire bond assembly as defined in claim 1, wherein said plurality of wires is insulated with a heat shrinking material.

9. A wire bond assembly comprising:
a package substrate;
a die positioned on said package substrate, a surface of said die including a perimeter portion and an inner portion having active circuitry thereon;
a plurality of leads on said package substrate surrounding said die;
a plurality of bond pads on said die, wherein said bond pads are arranged in a plurality of rows and a number of said rows are located in said perimeter portion of said die surface and a number of said rows are located in said inner portion of said die surface among said active circuitry, and wherein each said bond pad is spaced a predetermined distance from another of said bond pads; and
a plurality of wires connecting a certain number of said bond pads to a certain number of said leads.

10. A wire bond assembly as defined in claim 9, further including insulation covering a portion of each of said plurality of wires.

11. A wire bond assembly, comprising:
a die, wherein a surface of said die includes a perimeter portion and an inner portion having active circuitry thereon;
connection means on the surface of said die arranged in said perimeter portion and in said inner portion among said active circuitry;
a package substrate;
connection means on a surface of said substrate; and
transmission means for transmitting electrical signals between said connection means on said surface of said die and said connection means on said surface of said package substrate.

12. A wire bond assembly as defined in claim 11, further including insulation means for insulating each of said transmission means from another of said transmission means.

13. A wire bond assembly as claimed in claim 11, wherein said connection means on the surface of said die is a plurality of bond pads.

14. A wire bond assembly as defined in claim 11, wherein said connection means on the surface of said package substrate is a plurality of plated through holes.

15. A wire bond assembly as defined in claim 11, wherein said connection means on the surface of said package substrate is a plurality of contact pads

16. A wire bond assembly as defined in claim 11, wherein said transmission means is a plurality of wires extending between said connection means on the surface of said die and said connection means on the surface of said substrate.

17. A wire bond assembly as defined in claim 12, wherein said insulation means is a cured liquid.

18. A wire bond assembly as defined in claim 12, wherein said insulation means is a flat tape wrapped around said transmission means.

19. A wire bond assembly as defined in claim 12, wherein said insulation means is a heat shrink material.

20. A wire bond assembly comprising:
a die, wherein a surface of said die includes a perimeter portion and an inner portion having active circuitry thereon;
a plurality of bond pads on said perimeter portion and said inner portion of said surface of said die among said active circuitry;
a package substrate;
a plurality of leads on said package substrate; and
a plurality of wires connecting certain of said bond pads to certain of said leads.

21. A wire bond assembly as defined in claim 20, further including insulation on each of said wires; and wherein each of said wires can touch another of said wires without causing the wire bond assembly to malfunction.

22. A wire bond assembly as defined in claim 21, wherein an insulation start point and an insulation end point is defined for each said wire and said insulation is provided between said insulation start point and said insulation end point.

23. A method of forming a wire bond assembly including the steps of:
providing a package substrate including a plurality of leads;
providing a die including an upper surface, said upper surface including a perimeter portion and an inner portion having active circuitry thereon;
providing a plurality of bond pads in said perimeter portion and in said inner portion of said die among said active circuitry; and
providing a plurality of electrical connections between a certain number of said plurality of bond pads and a certain number of said plurality of leads.

24. A method of forming a wire bond assembly as defined in claim 23, further including the step of insulating each of said plurality of electrical connections.

25. A method as defined in claim 24, wherein said steps of providing a plurality of electrical connections and insulating includes the following steps:
designating a certain bond pad and a certain lead to be electrically connected;
determining an insulation start point and an insulation end point;
providing a conductive portion of wire;
providing an insulation;
bonding a first end of said conductive portion of wire to said bond pad;
pulling said wire in the direction of said lead until said insulation start point is reached;
continuing to pull said conductive portion of wire and simultaneously covering said conductive portion of wire with said insulation until said insulation end point is reached;
continuing to pull said conductive portion of wire until said lead is reached; and
bonding a second end of said conductive portion of wire to said lead.

26. A method as defined in claim 25, wherein said insulation provided is liquid and further including the step of heating and curing said insulation after bonding said second end of said conductive portion of wire.

27. A method as defined in claim 25, wherein said insulation provided is a tape and further including the step of heating said insulation after bonding said second end of said conductive portion of wire.

28. A method as defined in claim 25, wherein said insulation provided is a tape and further including the step of adhering said insulation to said conductive portion of wire.

29. A method as defined in claim 24, wherein said insulation is of a heat shrink type and further including the steps of:
heating said first end of said conductive portion of said wire to expose said conductive portion of said wire prior to bonding said first end to said bond pad; and
heating said second end of said conductive portion of said wire to expose said conductive portion of said wire prior to bonding said second end to said lead.
